(19) United States
(12) Patent Application Publication
(10) Pub. No.: US 2016/0296968 A1
(43) Pub. Date: Oct. 13, 2016

(54) Method and Device for Applying a Coating to a Substrate

(71) Applicant: SUSS MicroTec Lithography GmbH, Garching (DE)

(72) Inventor: Omar Fakhr, Brunnthal (DE)

(21) Appl. No.: 15/093,828

(22) Filed: Apr. 8, 2016

(30) Foreign Application Priority Data
Apr. 8, 2015 (NL) 2014597

(51) Int. Cl. B05D 1/34; H01L 21/027; B05D 1/28; B05C 5/02; B05D 1/02

(52) U.S. Cl. CPC B05D 1/34; B05C 5/02; B05D 1/02; B05D 1/28; H01L 21/0271

(57) ABSTRACT

A device for applying a coating to a substrate comprises a metering device by means of which a coating fluid can be applied to the substrate as a jet, and a solvent dispenser which is arranged eccentrically and to the side of the front end of the metering device in such a way that a predetermined amount of solvent can be administered to the front end of the metering device. This device can implement a method for applying a coating to a substrate wherein, before the coating fluid is applied, a predetermined amount of solvent is brought to the front end of the metering device in such a way that the solvent comes into contact with the coating fluid located there. After a waiting period, the coating fluid is subsequently applied to the substrate by means of the metering device.

The invention relates to a device by means of which a coating fluid can be applied to a substrate as a jet and to a method for applying a coating to a substrate.

### BACKGROUND OF THE INVENTION

The substrate may in particular be a wafer from which for example chips or MEMSs (microelectromechanical systems) are subsequently produced. For this purpose, photolithography processes may for example be used. In this case, the coating is a photoresist (resist) to be applied uniformly to the substrate. One example of a process for applying the photoresist is spin-coating, in which the substrate is rotated whilst the photoresist is being applied. Under the effect of centrifugal force, the photoresist is distributed uniformly on the surface of the substrate.

However, the device according to the invention and the method according to the invention are not limited to coating a wafer with photoresist, but in principle relate to any coating where the coating fluid is applied to a substrate as a jet, in such a way that it forms a homogeneous coating thereon with as uniform a layer thickness and as planar a surface as possible.

It has been found that the start of the coating process is problematic in that air bubbles (or else gas bubbles for coating in a gas atmosphere) may occur when the coating fluid jet impacts on the substrate, the bubbles being subsequently located within the coating. Depending on the viscosity of the coating fluid and the further processing steps (for example an idle period), it is not always ensured that these air bubbles rise to the surface of the applied coating and are eliminated. If air bubbles remain in the coating, they form an inhomogeneity in the coating. Further, there is the risk that they may lead to local elevations in the surface of the coating, since they take up some volume.

The object of the invention is to provide a device and a method for applying a coating to a substrate which prevent the occurrence of air or gas bubbles when the coating fluid jet impacts on the substrate.

### BRIEF DESCRIPTION OF THE INVENTION

To achieve this object, the invention provides a device comprising a metering device by means of which a coating fluid can be applied to the substrate as a jet, and a solvent dispenser which is arranged eccentrically and to the side of the front end of the metering device in such a way that a predetermined amount of solvent can be administered to the front end of the metering device. In the method according to the invention, before the coating fluid is being applied, a predetermined amount of solvent is brought to the front end of the metering device in such a way that the solvent comes into contact with the coating fluid located there. After a waiting period, the coating fluid is subsequently being applied to the substrate by means of the metering device.

The invention is based on the underlying idea of slightly diluting the front portion of the jet of coating fluid which impacts on the substrate, by means of the solvent. On the one hand, this reduces the tendency of the coating fluid to form air bubbles when it impacts on the substrate. The solvent appears to act as a lubricant in this context. On the other hand, the solvent leads to a slight dilution of the coating fluid such that any air bubbles which do occur can more easily rise to the surface of the coating and be eliminated. Since the solvent dispenser is arranged eccentrically and to the side of the front end of the metering device, it does not disrupt the normal coating process. Further, it only takes up very little space, and so enough space is left around the metering device for any other required components. “Arranged eccentrically and to the side of the front end of the metering device” means that the solvent dispenser is not integrated into the metering device or the nozzle which is part of the metering device, but arranged separate therefrom.

In one embodiment of the invention, the solvent dispenser is a spray nozzle which is directed towards and can spray solvent onto the front end of the metering device. This has the advantage that the solvent dispenser can be arranged at a distance from the front end of the metering device.

Preferably, the spray nozzle sprays the solvent in a direction substantially parallel to the plane defined by the front end of the metering device. As a result, the solvent is applied to the coating fluid located in the metering device in a tangential direction so the solvent remains on the coating fluid as a drop and does not penetrate into the coating fluid in the form of small droplets as a result of the spray pressure.

In an alternative embodiment, the solvent dispenser is formed as an administering arm which can supply a drop of solvent to the metering device. In this embodiment, a drop of solvent is produced at the front end of the solvent dispenser, comes into contact with the front end of the metering device, and subsequently moves, under the action of capillary forces, towards the coating fluid located in the metering device.

In one embodiment of the invention, the metering device and the solvent dispenser are adjustable relative to one another. This makes it possible to bring the drop produced at the solvent dispenser into contact with the metering device by bringing the solvent dispenser and the metering device close to one another and subsequently moving the two components apart again so that the solvent dispenser does not disrupt the coating process.

In a preferred embodiment, the coating fluid forms a concave meniscus at the front end of the metering device, and the solvent enters the meniscus. If it does not occur automatically as a result of the surface tension of the coating fluid, a meniscus of this type can be produced by pulling the coating fluid back slightly into the metering device after the end of the previous coating process. The meniscus makes it easier for the solvent to apply itself uniformly on the front end of the coating fluid contained in the metering device and thus on the front portion, which impacts on the substrate during coating, of the coating fluid jet.

The waiting period may be set as a function of the properties of the coating fluid and the solvent so as to prevent the occurrence of air bubbles in an optimum manner. In tests, waiting periods in the range of 10 to 120 s, preferably waiting periods of approximately 20 to 60 s, have been found to be suitable.

The coating fluid may be a photoresist. In this case, all materials normally used to dilute and/or treat photoresists of this type, for example acetone, are suitable as a solvent.

### BRIEF DESCRIPTION OF THE DRAWINGS

In the following, the invention is disclosed in greater detail with reference to various embodiments, which are shown in the accompanying drawings, in which:

FIG. 1 is a schematic view of a device for applying a coating to a substrate in the initial state;

FIG. 2 shows the device of FIG. 1 when solvent is being applied to the front end of the metering device;

FIG. 3 is a schematic view of a second embodiment of a device for applying a coating to a substrate;

FIG. 4 is a schematic sectional view of a coating fluid jet at the moment of impact on a substrate, the coating fluid having been treated using the device according to the invention and the method according to the invention;

FIG. 5 is a schematic sectional view of the coating obtained using the coating fluid jet of FIG. 4 on the substrate;

FIG. 6 shows in several schematic sectional views, in chronological succession, a coating fluid jet at the moment of impact on a substrate in a prior art coating process; and

FIG. 7 is a view corresponding to that of FIG. 5 of the coating obtained using the coating process of FIG. 6.

### DETAILED DESCRIPTION OF THE INVENTION

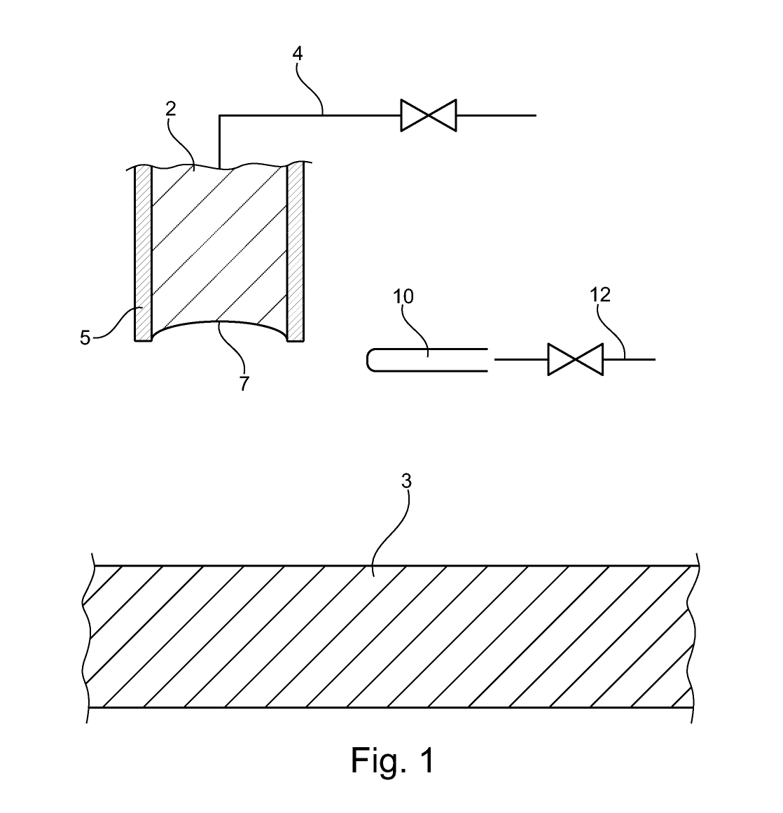

FIG. 1 schematically shows a device by means of which a coating fluid 2 can be applied to a substrate 3. The coating fluid 2 may for example be a photoresist (resist).

The coating fluid 2 is provided via a metering system 4, and can be applied to the substrate 3 in the form of a jet by a metering device 5. During application, the metering device and the substrate can be adjusted suitably relative to one another.

Using the device shown, in particular a coating method generally known as spin-coating can be carried out.

FIG. 1 shows the device between two coating processes. After the end of the previous coating process, the coating fluid 2 was sucked back slightly, and so the end face of the coating fluid located in the metering device 5 forms a concave meniscus 7.

The coating device is provided with a solvent dispenser 10, by means of which a predetermined amount of a solvent provided by a supply system 12 can be administered to the front end of the metering device 5. The solvent dispenser 10 is arranged eccentrically and to the side of the front end of the metering device 5, in other words outside the path of the coating fluid 2 from the metering device 5 to the substrate 3.

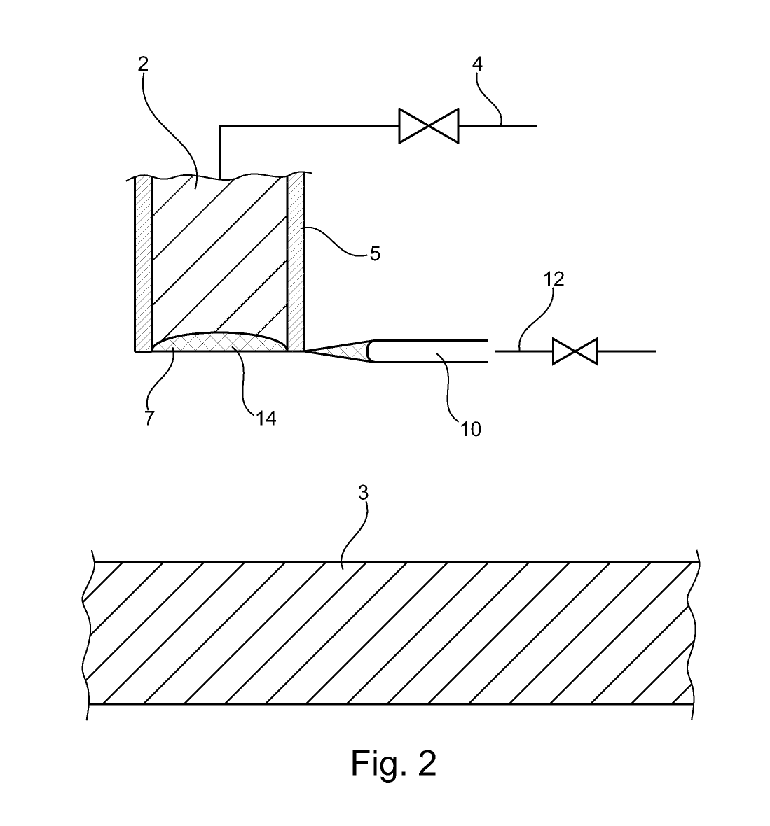

In the first embodiment shown in FIGS. 1 and 2, the solvent dispenser 10 is a spray nozzle by means of which the solvent can be sprayed from the side of the metering device 10 onto said metering device and/or onto the meniscus 7. Either the solvent may be sprayed onto the metering device in such a way that it enters the meniscus 7 under the action of capillary forces, or the solvent may be sprayed directly into the meniscus 7 tangentially.

What is of decisive importance is that a suitable amount of solvent 14 is applied by means of the solvent dispenser 10, and is located in the region of the meniscus 7 (see FIG. 2), in other words on the end face of the column of coating fluid located in the metering device 5.

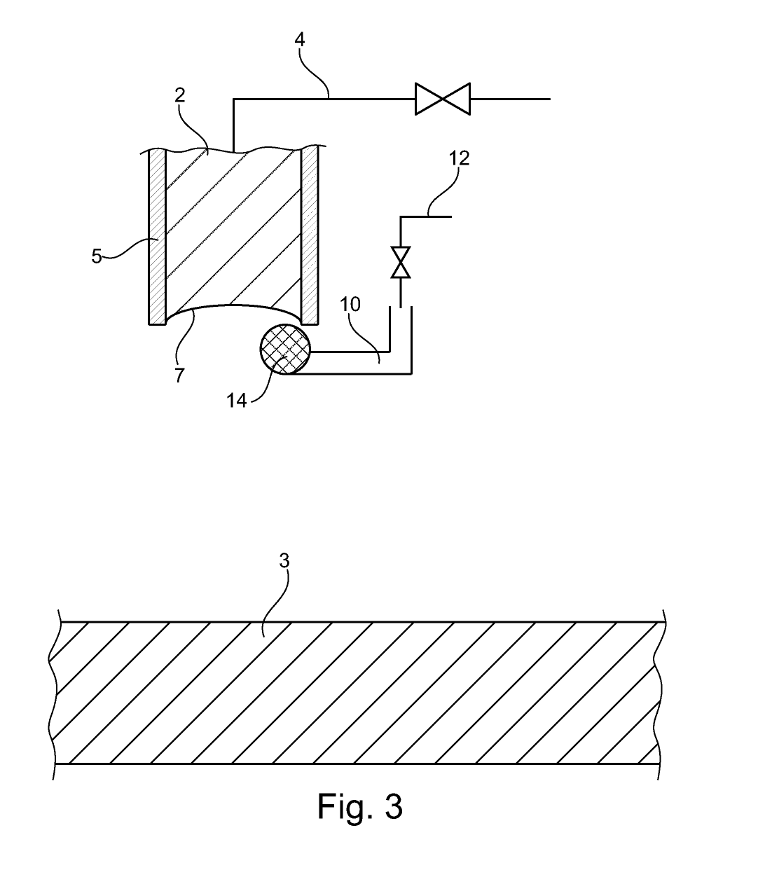

FIG. 3 shows a second embodiment. The same reference numerals are used for the components known from the first embodiment, and in this regard reference is made to the above explanations.

The difference from the first embodiment is that in the second embodiment the solvent dispenser 10 is configured as an administering arm, at the front end of which a drop of the solvent 14 can be produced. This drop is subsequently brought into contact with the front end of the metering device 5 or with the meniscus 7 at the front end of the column of coating fluid 2 located in the metering device 5. For this purpose, the metering device 5 and the solvent dispenser 10 are adjusted suitably relative to one another, for example using a combination of radial and vertical movement.

When the substrate 3 is to be coated with the coating fluid 2, initially the solvent 14 is applied to the end face of the column of coating fluid 2 located in the metering device 5. This can be done either by spraying (see FIG. 2) or by mechanically transferring a drop of solvent onto the metering device 5 (see FIG. 3).

The solvent is applied a predetermined length of time before the start of the coating process so that a desired waiting period can pass before the coating fluid 2 is applied to the substrate 3 in the form of a jet.

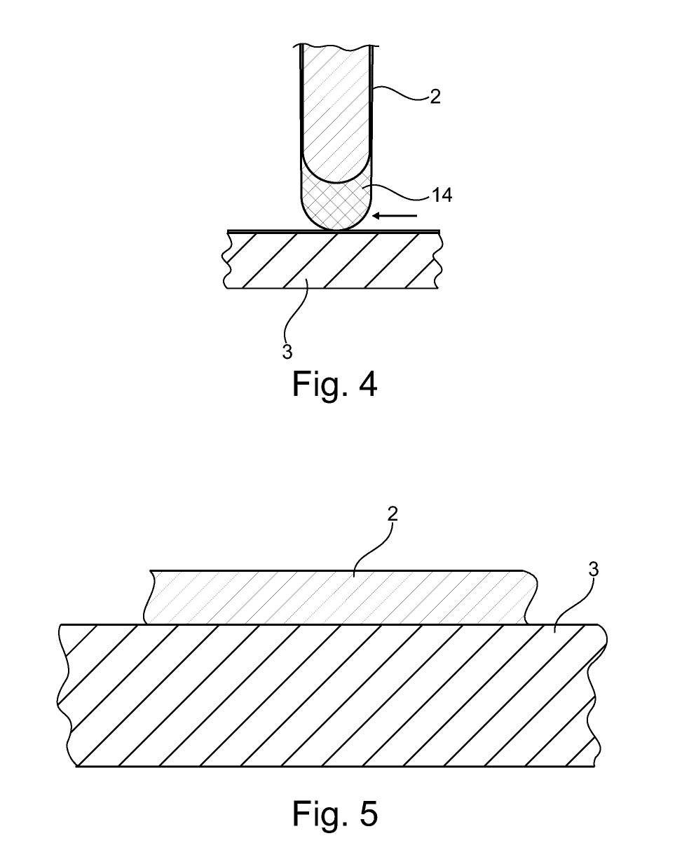

The moment when the front end of the jet of coating fluid 2 impacts on the substrate 3 is shown schematically in FIG. 4. FIG. 4 also shows the solvent 14 which surrounds the front end of the jet of coating fluid 2. It has been found that, by using the solvent, air bubbles can be prevented from forming when the front end of the jet of coating fluid 2 impacts on the substrate 3. This is possible due to the viscosity which is altered by the solvent. The solvent may possibly also act in the manner of a lubricant.

FIG. 5 schematically shows the coating fluid 2, which has been applied to the substrate 3 as a coating. It can be seen that there are no air bubbles enclosed in the coating and that the coating has a constant layer thickness as well as a planar surface.

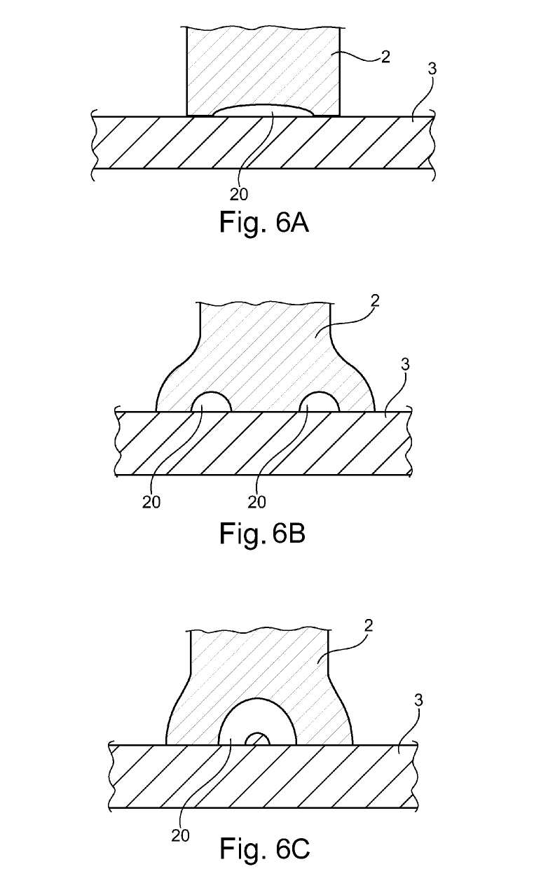

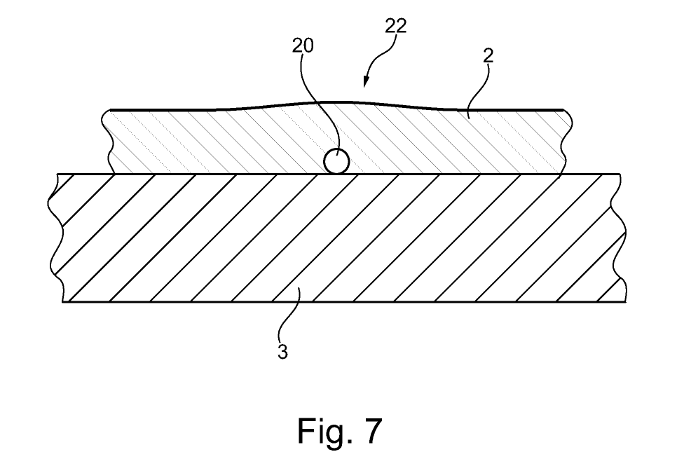

FIG. 6 schematically shows the impact of the front end of a jet of coating fluid 2 on a substrate 3, there not being any solvent at the front end of the jet.

When the front end of the coating fluid jet impacts on the substrate 3, an air film is formed (see FIG. 6a) which is laterally surrounded by the coating fluid 2. This air contracts such that, via an intermediate toroidal state (see FIG. 6b), it forms an air bubble (see FIG. 6c) which then remains in the formed coating as an air bubble 20 (see FIG. 7). Air bubbles of this type not only form an inhomogeneity in the coating, but also lead to a local bulge in the surface of the coating (see region 22).

1. A device for applying a coating to a substrate, comprising a metering device by means of which a coating fluid can be applied to said substrate as a jet, and a solvent dispenser which is arranged eccentrically and laterally of a front end of said metering device so that a predetermined amount of solvent can be administered to said front end of said metering device.

2. The device of claim 1 wherein said solvent dispenser is a spray nozzle which is directed towards said front end of said metering device.

3. The device of claim 1 wherein said solvent dispenser is formed as an administering arm which can supply a drop of said solvent to said metering device.

4. The device of claim 3 wherein said metering device and said solvent dispenser are adjustable relative to one another.

5. The device of claim 1 wherein said coating is formed by a coating fluid which is a photoresist.

6. A method for applying a coating to a substrate by means of a device for applying a coating to a substrate, said device comprising a metering device by means of which a coating fluid can be applied to said substrate as a jet, and a solvent dispenser which is arranged eccentrically and laterally of a front end of said metering device so that a predetermined amount of solvent can be administered to said front end of said metering device, the method comprising the following steps:
before a coating fluid is being applied, a predetermined amount of solvent is brought to said front end of said metering device such that said solvent comes into contact with said coating fluid located there;
after a waiting period, said coating fluid is subsequently being applied to said substrate by means of said metering device.

7. The method of claim 6 wherein said coating fluid forms a concave meniscus at said front end of said metering device and wherein said solvent enters said meniscus.

8. The method of claim 6 wherein said solvent is sprayed onto said front end of said metering device.

9. The method of claim 8 wherein said solvent is sprayed in a direction substantially parallel to a plane defined by said front end of said metering device.

10. The method of claim 6 wherein said metering device and said solvent dispenser are adjusted relative to one another in such a way that said solvent reaches said front end of said metering device.

11. The method of claim 6 wherein said waiting period is approximately 10 to 120 s, preferably approximately 20 to 60 s.
